(19) United States
(12) Patent Application Publication
(10) Pub. No.: US 2026/0251712 A1
(43) Pub. Date: Aug. 27, 2026

(54) MEMORY DEVICE CONFIGURED FOR DETECTING A CONNECTION FAILURE BETWEEN SIGNAL PATHS

(71) Applicant: SK hynix Inc., Icheon-si Gyeonggi-do (KR)

(72) Inventors: Min Kyu MOON, Icheon-si Gyeonggi-do (KR); Kyung Jun CHO, Icheon-si Gyeonggi-do (KR)

(73) Assignee: SK hynix Inc., Icheon-si Gyeonggi-do (KR)

(21) Appl. No.: 19/282,531

(22) Filed: Jul. 28, 2025

(30) Foreign Application Priority Data
Feb. 26, 2025 (KR) 10-2025-0025395

(51) Int. Cl. G01R 31/3185; G01R 31/317

(52) U.S. Cl. CPC G01R 31/31855; G01R 31/31725; G01R 31/318541

(57) ABSTRACT

A memory device includes a base chip and a core chip that are stacked through a signal path. The base chip and the core chip drive the signal path after the start of a scan operation and detect a connection fail of the signal path based on a logic level at which an internal node that is connected to the signal path is driven. The base chip adjusts timing at which the logic level of the internal node is latched.

### CROSS-REFERENCE TO RELATED APPLICATION

The present application claims priority under 35 U.S.C. §119(a) to Korean Patent Application No. 10-2025-0025395, filed in the Korean Intellectual Property Office on February 26, 2025, the entire contents of which application is incorporated herein by reference.

### BACKGROUND

### Technical Field

The present disclosure generally relates to a memory device, and more particularly, to a memory device that detects a connection failure between signal paths of a stacked plurality of chips.

As technology for manufacturing a memory device progresses, a packaging technology for a plurality of core chips for implementing the memory device with high integration and high performance progresses as well. In packaging technologies for implementing the memory device, a technology relating to a three-dimensional structure in which a plurality of core chips is vertically stacked out of the two-dimensional structure in which a plurality of core chips is flatly disposed on a printed circuit board (PCB) is variously developed. The memory device having the three-dimensional structure may be implemented by stacking a plurality of core chips through a through silicon via (TSV) (hereinafter referred to as a “through via”), like high bandwidth memory (HBM), or may be implemented by stacking a plurality of core chips through wire bonding.

As integration and performance become higher, there is a need for methods of detecting a connection fail between TSVs for stacking a plurality of core chips.

### SUMMARY

In an embodiment, a memory device may include core chip vertically stacked on a base chip through a portion of a signal path located between the core chip and the base chip, the core chip spaced apart from the base chip with the portion of the signal path. The base chip and the core chip drive the signal path after the start of a scan operation and detect a connection fail of the signal path based on a logic level at which an internal node that is connected to the signal path is driven. The base chip adjusts timing at which the logic level of the internal node is latched.

In an embodiment, a memory device may include a core chip vertically stacked on a base chip through a first portion of a signal path located between the core chip and the base chip and a second portion of a voltage path located between the core chip and the base chip, the core chip spaced apart from the base chip by the first and second portions of the signal and voltage paths, respectively. The base chip and the core chip drive the signal path after the start of a scan operation, detect a connection fail of the signal path and a connection fail of the signal path and the voltage path based on a logic level at which an internal node that is connected to the signal path is driven. The base chip adjusts timing at which the logic level of the internal node is latched.

### BRIEF DESCRIPTION OF THE DRAWINGS

FIG. 1 is a block diagram illustrating a construction of a memory system according to an embodiment of the present disclosure.

FIG. 2 is a block diagram illustrating a construction of a memory device according to an embodiment of the present disclosure.

FIG. 3 is a block diagram illustrating a construction of a base chip according to an embodiment of the present disclosure.

FIG. 4 is a block diagram illustrating a construction of a test control circuit according to an embodiment of the present disclosure.

FIG. 5 is a diagram illustrating a construction of a cycle signal generation circuit according to an embodiment of the present disclosure.

FIG. 6 is a block diagram illustrating a construction of a scan pulse generation circuit according to an embodiment of the present disclosure.

FIG. 7 is a timing diagram for describing an operation of a counter according to an embodiment of the present disclosure.

FIG. 8 is a block diagram illustrating a construction of a shifting circuit according to an embodiment of the present disclosure.

FIG. 9 is a diagram illustrating a construction of a latch signal generation circuit according to an embodiment of the present disclosure.

FIG. 10 is a block diagram illustrating a construction of a base test circuit according to an embodiment of the present disclosure.

FIG. 11 is a diagram illustrating a construction of a first fail signal generation circuit according to an embodiment of the present disclosure.

FIG. 12 is a block diagram illustrating a construction of a fourth core chip according to an embodiment of the present disclosure.

FIG. 13 is a block diagram illustrating a construction of a core test circuit according to an embodiment of the present disclosure.

FIG. 14 is a circuit diagram illustrating a construction of a first path driving circuit according to an embodiment of the present disclosure.

FIGS. 15, 16, 17 and 18, are diagrams for describing scan operations of the memory device according to embodiments of the present disclosure.

### DETAILED DESCRIPTION

In the descriptions of the following embodiments, the term "preset" indicates that the numerical value of a parameter is previously decided, when the parameter is used in a process or algorithm. According to an embodiment, the numerical value of the parameter may be set when the process or algorithm is started or while the process or algorithm is performed.

Terms such as "first" and "second," which are used to distinguish among various components, are not limited by the components. For example, a first component may be referred to as a second component, and vice versa.

When one component is referred to as being "coupled" or "connected" to another component, it should be understood that the components may be directly coupled or connected to each other or coupled or connected to each other through another component interposed therebetween. In contrast, when one component is referred to as being "directly coupled" or "directly connected" to another component, it should be understood that the components are directly coupled or connected to each other without another component interposed therebetween.

A "logic high level" and a "logic low level" are used to describe the logic levels of signals. A signal having a "logic high level" is distinguished from a signal having a "logic low level." For example, when a signal having a first voltage corresponds to a signal having a "logic high level," a signal having a second voltage may correspond to a signal having a "logic low level." According to an embodiment, a "logic high level" may be set to a voltage higher than a "logic low level." According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

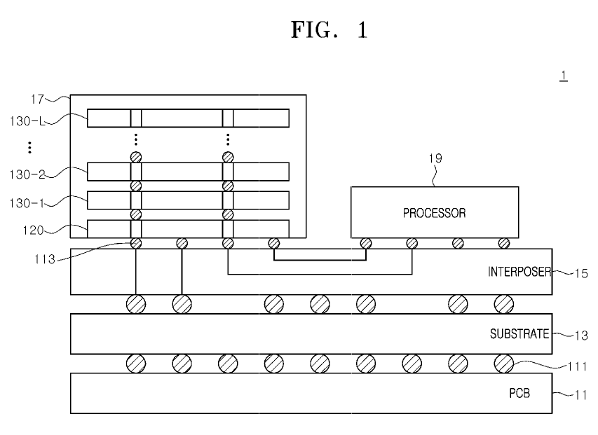

FIG. 1 is a block diagram illustrating a construction of a memory system 1 according to an embodiment of the present disclosure. As illustrated in FIG. 1, the memory system 1 may include a PCB 11, a substrate 13, an interposer 15, a memory device 17, and a processor 19.

The PCB 11 connects several electronic parts in order to form an electronic circuit (not illustrated). A copper layer, a solder mask, and a silk screen may be formed in the PCB 11. A circuit path along which a signal or power is transmitted may be formed in the copper layer. In an embodiment, the solder mask prevents or mitigates damage to the circuit and protects a specific region in which a part may be soldered. Furthermore, the silk screen displays the locations of electronic parts or information in the form of letters or symbols printed on a surface of the PCB 11.

The substrate 13 is formed over the PCB 11 through bump pads, for example, 111, and may mechanically support the interposer 15, the memory device 17, and the processor 19. The substrate 13 may be usually used as an insulator as a material that is a physical base of the PCB 11. Materials of the substrate 13 include flame retardant grade four (FR4) that is an insulator made of glass fiber and epoxy resin, ceramic that is mainly used in a high frequency circuit or a high temperature environment because the ceramic can withstand a high temperature and has excellent thermal conductivity, and polyimide that is used as a basic material of a flexible PCB due to a flexible characteristic.

The interposer 15 is formed over the substrate 13 through bump pads, and may include electronic parts having form factors or pin arrangements not matched, for example, wires that connect the memory device 17 and the processor 19. The interposer 15 may convert signals at different interfaces.

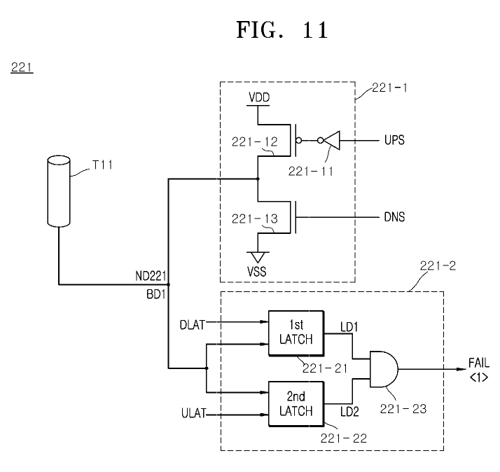

The memory device 17 may be formed over the interposer 15 through micro bump pads, for example, 113. The memory device 17 may store data applied by the processor 19 or may output stored data to the processor 19 under the control of the processor 19. The memory device 17 may include a base chip 120 and a plurality of core chips 130-1 to 130-L. The plurality of core chips 130-1 to 130-L may be vertically stacked over the base chip 120 through micro bump pads. The base chip 120 and the plurality of core chips 130-1 to 130-L may be vertically connected through vias. The base chip 120 may drive a signal path after the start of a scan operation. A method of detecting a connection fail between the TSVs may be performed by turning on a PMOS transistor that is connected to the TSV of a core chip disposed at the top layer, turning off an NMOS transistor that is connected to the TSV of a base chip disposed at the bottom, and then performing a scan operation (e.g., a TSV open short test) of detecting that the TSV is driven at a set logic level. Such a scan operation (e.g., the TSV open short test) may detect an open fail in which TSVs are disconnected, but may be difficult to detect a short fail in which TSVs are connected. Thus, in an embodiment, the base chip 120 may detect a connection fail of the signal path based on a logic level at which an internal node (ND221 in FIG. 11) that is connected to the signal path is driven after the start of a scan operation. The base chip 120 may adjust timing at which the logic level of the internal node (ND221 in FIG. 11) that is connected to the signal path is latched after the start of a scan operation. The signal path may be set as a path along which the through via and the micro bump pad are connected.

The core chip 130-L that is disposed at the top, among the plurality of core chips 130-1 to 130-L, may drive the signal path after the start of a scan operation. The plurality of core chips 130-1 to 130-L may input and output data through the signal paths. Each of the plurality of core chips 130-1 to 130-L may store data and output data stored in each of the plurality of core chips 130-1 to 130-L. Each of the plurality of core chips 130-1 to 130-L may include a plurality of channel regions that independently operates. Each of the plurality of channel regions may be assigned a channel that independently operates, and may receive or transmit data. The number L of core chips 130-1 to 130-L may be 4, 8, 12, or 16. For example, when each of the core chips 130-1 to 130-12 has eight channels, each of the core chips 130-1 to 130-4, the core chips 130-5 to 130-8, and the core chips 130-9 to 130-12 may include 32 channel regions, and may transmit and receive data to and from the processor 19 in a rank unit including 32 channels.

The processor 19 may detect a signal transmission path in which a fail has occurred, among the signal transmission paths of the base chip 120 through the wires formed within the interposer 15.

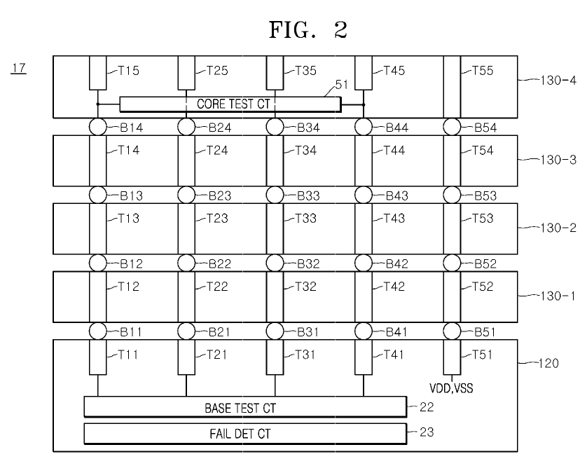

FIG. 2 is a block diagram illustrating a construction of the memory device 17 according to an embodiment of the present disclosure. As illustrated in FIG. 2, the memory device 17 may include a base chip 120, a first core chip 130-1, a second core chip 130-2, a third core chip 130-3, and a fourth core chip 130-4.

The base chip 120 may be electrically connected to first to fourth signal paths and a voltage path. Through vias T11, T12, T13, T14, and T15 and micro bump pads B11, B12, B13, and B14 may be electrically connected along the first signal path. Through vias T21, T22, T23, T24, and T25 and micro bump pads B21, B22, B23, and B24 may be electrically connected along the second signal path. Through vias T31, T32, T33, T34, and T35 and micro bump pads B31, B32, B33, and B34 may be electrically connected along the third signal path. Through vias T41, T42, T43, T44, and T45 and micro bump pads B41, B42, B43, and B44 may be electrically connected along the fourth signal path. The first to fourth signal paths may be implemented as paths along which signals that control operations of the first core chip 130-1, the second core chip 130-2, the third core chip 130-3, and the fourth core chip 130-4 are input and output. Through vias T51, T52, T53, T54, and T55 and micro bump pads B51, B52, B53, and B54 may be electrically connected along the voltage path. The voltage path may be set as a path along which a source voltage VDD and a ground voltage VSS supplied to the first core chip 130-1, the second core chip 130-2, the third core chip 130-3, and the fourth core chip 130-4 are applied. The voltage path has been illustrated as one voltage path, but a path to which the source voltage VDD is applied and a path to which the ground voltage VSS is applied may be separately implemented.

The through vias T11, T12, T13, T14, T15, T21, T22, T23, T24, T25, T31, T32, T33, T34, T35, T41, T42, T43, T44, T45, T51, T52, T53, T54, and T55 may each be implemented in a cylindrical form in each through via is made of a conductive material so that the through vias are vertically stacked through the base chip 12, the first core chip 130-1, the second core chip 30, the third core chip 40, and the fourth core chip 50. The micro bump pads B11, B12, B13, B14, B21, B22, B23, B24, B31, B32, B33, B34, B41, B42, B43, B44, B51, B52, B53, and B54 may each be implemented in a ball form in which each micro bump pad is made of a conductive material so that the micro bump pads are directly connected to a circuit substrate. The first to fourth signal paths and the voltage path each include five through vias, but may each includes various numbers of through vias according to an embodiment.

The base chip 120 may include the through vias T11, T21, T31, T41, and T51, a base test circuit (BASE TEST CT) 22, and a fail detection circuit (FAIL DET CT) 23.

The through via T11 may be electrically connected to the micro bump pad B11. The through via T21 may be electrically connected to the micro bump pad B21. The through via T31 may be electrically connected to the micro bump pad B31. The through via T41 may be electrically connected to the micro bump pad B41. The through via T51 may be electrically connected to the micro bump pad B51.

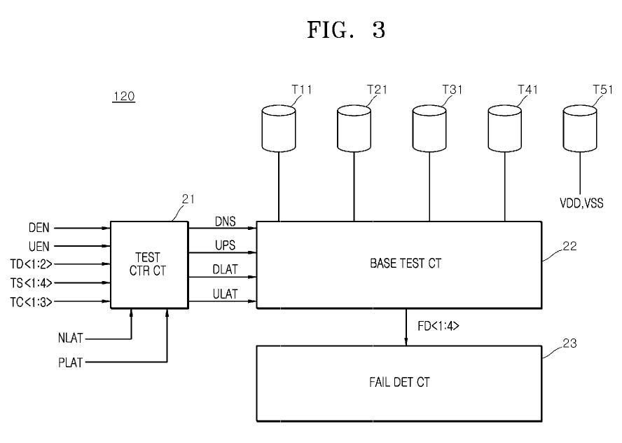

The base test circuit 22 may drive the through vias T11, T21, T31, and T41 through any one of a PMOS transistor and an NMOS transistor after the start of a scan operation. The base test circuit 22 may drive the through vias T11, T21, T31, and T41 to the source voltage VDD through the PMOS transistor after the start of an up scan operation of a scan operation. The base test circuit 22 may drive the through vias T11, T21, T31, and T41 to the ground voltage VSS through the NMOS transistor after the start of a down scan operation of a scan operation. The base test circuit 22 may adjust timing at which the logic level of the internal node (ND221 in FIG. 11) is latched after the start of a scan operation. The base test circuit 22 may generate fail detection signals (FD<1:4> in FIG. 3) by detecting the logic level of the internal node (ND221 in FIG. 11) that is connected to the through vias T11, T21, T31, and T41 after the start of a scan operation.

The fail detection circuit 23 may detect a connection fail between the first to fourth signal paths based on the fail detection signals (FD<1:4> in FIG. 3) after the start of a scan operation.

The first core chip 130-1 may be electrically connected to the micro bump pads B11, B21, B31, B41, and B51 and stacked over the base chip 120. In an embodiment, the first core chip 130-1 is vertically stacked on the base chip 120 through a portion (e.g., micro bump B11) of a signal path (e.g., first signal path) located between the first core chip 130-1 and the base chip 120. In an embodiment, the first core chip 130-1 is spaced apart from the base chip 120 with the portion (e.g., micro bump B11) of the signal path (e.g., first signal path). In an embodiment, the first core chip 130-1 is vertically stacked on the base chip 120 through a portion (e.g., micro bump B21) of a signal path (e.g., second signal path) located between the first core chip 130-1 and the base chip 120. In an embodiment, the first core chip 130-1 is spaced apart from the base chip 120 with the portion (e.g., micro bump B21) of the signal path (e.g., second signal path). In an embodiment, the first core chip 130-1 is vertically stacked on the base chip 120 through a portion (e.g., micro bump B31) of a signal path (e.g., third signal path) located between the first core chip 130-1 and the base chip 120. In an embodiment, the first core chip 130-1 is spaced apart from the base chip 120 with the portion (e.g., micro bump B31) of the signal path (e.g., third signal path). In an embodiment, the first core chip 130-1 is vertically stacked on the base chip 120 through a portion (e.g., micro bump B41) of a signal path (e.g., fourth signal path) located between the first core chip 130-1 and the base chip 120. In an embodiment, the first core chip 130-1 is spaced apart from the base chip 120 with the portion (e.g., micro bump B41) of the signal path (e.g., fourth signal path). In an embodiment, the first core chip 130-1 is vertically stacked on the base chip 120 through a portion (e.g., micro bump B51) of a voltage path located between the first core chip 130-1 and the base chip 120. In an embodiment, the first core chip 130-1 is spaced apart from the base chip 120 with the portion (e.g., micro bump B51) of the voltage path.

The first core chip 130-1 may include the through vias T12, T22, T32, T42, and T52.

The through via T12 may be electrically connected between the micro bump pad B11 and the micro bump pad B12. The through via T22 may be electrically connected between the micro bump pad B21 and the micro bump pad B22. The through via T32 may be electrically connected between the micro bump pad B31 and the micro bump pad B32. The through via T42 may be electrically connected between the micro bump pad B41 and the micro bump pad B42. The through via T52 may be electrically connected between the micro bump pad B51 and the micro bump pad B52.

The second core chip 130-2 may be electrically connected to the micro bump pads B12, B22, B32, B42, and B52 and stacked over the first core chip 130-1. In an embodiment, the second core chip 130-2 is vertically stacked on the first core chip 130-1 through a portion (e.g., micro bump B12) of a signal path (e.g., first signal path) located between the second core chip 130-2 and the first core chip 130-1. In an embodiment, the second core chip 130-2 is spaced apart from the first core chip 130-1 with the portion (e.g., micro bump B12) of the signal path (e.g., first signal path). In an embodiment, the second core chip 130-2 is vertically stacked on the first core chip 130-1 through a portion (e.g., micro bump B22) of a signal path (e.g., second signal path) located between the second core chip 130-2 and the first core chip 130-1. In an embodiment, the second core chip 130-2 is spaced apart from the first core chip 130-1 with the portion (e.g., micro bump B22) of the signal path (e.g., second signal path). In an embodiment, the second core chip 130-2 is vertically stacked on the first core chip 130-1 through a portion (e.g., micro bump B32) of a signal path (e.g., third signal path) located between the second core chip 130-2 and the first core chip 130-1. In an embodiment, the second core chip 130-2 is spaced apart from the first core chip 130-1 with the portion (e.g., micro bump B32) of the signal path (e.g., third signal path). In an embodiment, the second core chip 130-2 is vertically stacked on the first core chip 130-1 through a portion (e.g., micro bump B42) of a signal path (e.g., fourth signal path) located between the second core chip 130-2 and the first core chip 130-1. In an embodiment, the second core chip 130-2 is spaced apart from the first core chip 130-1 with the portion (e.g., micro bump B42) of the signal path (e.g., fourth signal path). In an embodiment, the second core chip 130-2 is vertically stacked on the first core chip 130-1 through a portion (e.g., micro bump B52) of a voltage path located between the second core chip 130-2 and the first core chip 130-1. In an embodiment, the second core chip 130-2 is spaced apart from the first core chip 130-1 with the portion (e.g., micro bump B52) of the voltage path.

The second core chip 130-2 may include the through vias T13, T23, T33, T43, and T53.

The through via T13 may be electrically connected between the micro bump pad B12 and the micro bump pad B13. The through via T23 may be electrically connected between the micro bump pad B22 and the micro bump pad B23. The through via T33 may be electrically connected between the micro bump pad B32 and the micro bump pad B33. The through via T43 may be electrically connected between the micro bump pad B42 and the micro bump pad B43. The through via T53 may be electrically connected between the micro bump pad B52 and the micro bump pad B53.

The third core chip 130-3 may be electrically connected to the micro bump pads B13, B23, B33, B43, and B53 and stacked over the second core chip 130-2. In an embodiment, the third core chip 130-3 is vertically stacked on the second core chip 130-2 through a portion (e.g., micro bump B13) of a signal path (e.g., first signal path) located between the third core chip 130-3 and the second core chip 130-2. In an embodiment, the third core chip 130-3 is spaced apart from the second core chip 130-2 with the portion (e.g., micro bump B13) of the signal path (e.g., first signal path). In an embodiment, the third core chip 130-3 is vertically stacked on the second core chip 130-2 through a portion (e.g., micro bump B23) of a signal path (e.g., second signal path) located between the third core chip 130-3 and the second core chip 130-2. In an embodiment, the third core chip 130-3 is spaced apart from the second core chip 130-2 with the portion (e.g., micro bump B23) of the signal path (e.g., second signal path). In an embodiment, the third core chip 130-3 is vertically stacked on the second core chip 130-2 through a portion (e.g., micro bump B33) of a signal path (e.g., third signal path) located between the third core chip 130-3 and the second core chip 130-2. In an embodiment, the third core chip 130-3 is spaced apart from the second core chip 130-2 with the portion (e.g., micro bump B33) of the signal path (e.g., third signal path). In an embodiment, the third core chip 130-3 is vertically stacked on the second core chip 130-2 through a portion (e.g., micro bump B43) of a signal path (e.g., fourth signal path) located between the third core chip 130-3 and the second core chip 130-2. In an embodiment, the third core chip 130-3 is spaced apart from the second core chip 130-2 with the portion (e.g., micro bump B43) of the signal path (e.g., fourth signal path). In an embodiment, the third core chip 130-3 is vertically stacked on the second core chip 130-2 through a portion (e.g., micro bump B53) of a voltage path located between the third core chip 130-3 and the second core chip 130-2. In an embodiment, the third core chip 130-3 is spaced apart from the second core chip 130-2 with the portion (e.g., micro bump B53) of the voltage path.

The third core chip 130-3 may include the through vias T14, T24, T34, T44, and T54.

The through via T14 may be electrically connected between the micro bump pad B13 and the micro bump pad B14. The through via T24 may be electrically connected between the micro bump pad B23 and the micro bump pad B24. The through via T34 may be electrically connected between the micro bump pad B33 and the micro bump pad B34. The through via T44 may be electrically connected between the micro bump pad B43 and the micro bump pad B44. The through via T54 may be electrically connected between the micro bump pad B53 and the micro bump pad B54.

The fourth core chip 130-4 may be electrically connected to the micro bump pads B14, B24, B34, B44, and B54 and stacked over the third core chip 130-3. In an embodiment, the fourth core chip 130-4 is vertically stacked on the third core chip 130-3 through a portion (e.g., micro bump B14) of a signal path (e.g., first signal path) located between the fourth core chip 130-4 and the third core chip 130-3. In an embodiment, the fourth core chip 130-4 is spaced apart from the third core chip 130-3 with the portion (e.g., micro bump B14) of the signal path (e.g., first signal path). In an embodiment, the fourth core chip 130-4 is vertically stacked on the third core chip 130-3 through a portion (e.g., micro bump B24) of a signal path (e.g., second signal path) located between the fourth core chip 130-4 and the third core chip 130-3. In an embodiment, the fourth core chip 130-4 is spaced apart from the third core chip 130-3 with the portion (e.g., micro bump B24) of the signal path (e.g., second signal path). In an embodiment, the fourth core chip 130-4 is vertically stacked on the third core chip 130-3 through a portion (e.g., micro bump B34) of a signal path (e.g., third signal path) located between the fourth core chip 130-4 and the third core chip 130-3. In an embodiment, the fourth core chip 130-4 is spaced apart from the third core chip 130-3 with the portion (e.g., micro bump B34) of the signal path (e.g., third signal path). In an embodiment, the fourth core chip 130-4 is vertically stacked on the third core chip 130-3 through a portion (e.g., micro bump B44) of a signal path (e.g., fourth signal path) located between the fourth core chip 130-4 and the third core chip 130-3. In an embodiment, the fourth core chip 130-4 is spaced apart from the third core chip 130-3 with the portion (e.g., micro bump B44) of the signal path (e.g., fourth signal path). In an embodiment, the fourth core chip 130-4 is vertically stacked on the third core chip 130-3 through a portion (e.g., micro bump B54) of a voltage path located between the fourth core chip 130-4 and the third core chip 130-3. In an embodiment, the fourth core chip 130-4 is spaced apart from the third core chip 130-3 with the portion (e.g., micro bump B54) of the voltage path.

The fourth core chip 130-4 may include the through vias T15, T25, T35, T45, and T55 and a core test circuit (CORE TEST CT) 51.

The core test circuit 51 may drive the through vias T15, T25, T35, and T45 through any one of a PMOS transistor and an NMOS transistor after the start of a scan operation. The core test circuit 51 may drive the through vias T15, T25, T35, and T45 to the source voltage VDD through the PMOS transistor after the start of a down scan operation of a scan operation. The core test circuit 51 may drive the through vias T15, T25, T35, and T45 to the ground voltage VSS through the NMOS transistor after the start of an up scan operation of a scan operation.

In FIG. 2, the first core chip 130-1, the second core chip 130-2, the third core chip 130-3, and the fourth core chip 130-4 have been vertically stacked over the base chip 120, but various numbers of core chips, such as 8 or 16, may be stacked according to an embodiment.

In FIG. 2, the base chip 120, the first core chip 130-1, the second core chip 130-2, the third core chip 130-3, and the fourth core chip 130-4 have been vertically stacked in the memory device 17 through the TSVs like, for example, high bandwidth memory (HBM). However, according to an embodiment, a plurality of core chips may be stacked through wire bonding. The wire bonding may be set as a signal path for signals that are input and output to and from the base chip 120, the first core chip 130-1, the second core chip 130-2, the third core chip 130-3, and the fourth core chip 130-4 according to an embodiment.

FIG. 3 is a block diagram illustrating a construction of the base chip 120 according to an embodiment of the present disclosure. The base chip 120 may include a test control circuit (TEST CTR CT) 21, the base test circuit 22, and the fail detection circuit 23.

The test control circuit 21 may generate a down scan signal DNS and an up scan signal UPS, based on a down scan enable signal DEN and an up scan enable signal UEN. The down scan enable signal DEN may be set as a signal that is enabled after the start of a down scan operation of a scan operation. The up scan enable signal UEN may be set as a signal that is enabled after the start of an up scan operation of a scan operation.

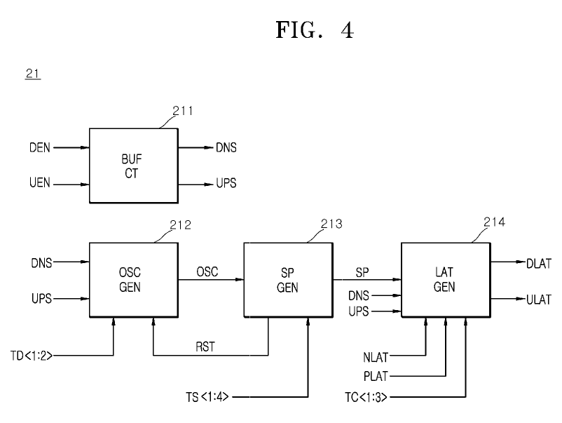

The test control circuit 21 may generate a down latch signal DLAT and an up latch signal ULAT based on first and second test delay signals TD<1:2>, first to fourth test selection signals TS<1:4>, and a first test control signal TC<1> when any one of the down scan enable signal DEN and the up scan enable signal UEN is enabled. The first and second test delay signals TD<1:2> may each be set as a signal that adjusts the pulse width of a cycle signal (OSC in FIG. 4). The first to fourth test selection signals TS<1:4> may each be set as a signal that adjusts timing at which the logic level of the internal node (ND221 in FIG. 11) is latched. The first test control signal TC<1> may be set as a signal that generates the down latch signal DLAT and the up latch signal ULAT from a scan pulse (SP in FIG. 4) that is generated after the start of a scan operation.

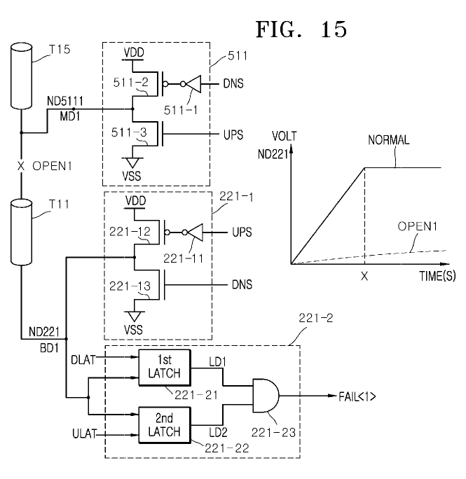

The test control circuit 21 may generate the down latch signal DLAT and the up latch signal ULAT, based on a normal latch signal NLAT, a pad latch signal PLAT, and second and third test control signals TC<2:3>. The normal latch signal NLAT may be set as a signal that is enabled at a set timing (timing X in FIGS. 15 to 18) after the start of a scan operation in order to latch the logic level of the internal node (ND221 in FIG. 11). The pad latch signal PLAT may be set as a signal that is input in order to latch the logic level of the internal node (ND221 in FIG. 11) through a pad that is connected to an external device. The second test control signal TC<2> may be set as a signal that generates the down latch signal DLAT and the up latch signal ULAT from the normal latch signal NLAT. The third test control signal TC<3> may be set as a signal that generates the down latch signal DLAT and the up latch signal ULAT from the pad latch signal PLAT.

The base test circuit 22 may be electrically connected to the through vias T11, T21, T31, and T41. The base test circuit 22 may drive the through vias T11, T21, T31, and T41 through any one of the PMOS transistor and the NMOS transistor after the start of a scan operation. The base test circuit 22 may drive the through vias T11, T21, T31, and T41 through any one of the PMOS transistor and the NMOS transistor based on the down scan signal DNS and the up scan signal UPS after the start of a scan operation. The base test circuit 22 may adjust timing at which the down latch signal DLAT and the up latch signal ULAT that latch the logic level of the internal node (ND221 in FIG. 11) that is connected to the signal path are generated, after the start of a scan operation. The base test circuit 22 may latch the logic level of the internal node (ND221 in FIG. 11) that is connected to the through vias T11, T21, T31, and T41 based on the down latch signal DLAT and the up latch signal ULAT after the start of a scan operation. The base test circuit 22 may generate the first to fourth fail detection signals FD<1:4> by detecting the logic level of the internal node (ND221 in FIG. 11) that is connected to the through vias T11, T21, T31, and T41 latched after the start of a scan operation.

The fail detection circuit 23 may detect a connection fail between the through vias T11, T21, T31, and T41 based on the first to fourth fail detection signals FD<1:4> after the start of a scan operation. The fail detection circuit 23 may detect a first open fail in which the through vias T11, T21, T31, and T41 are disconnected by detecting the logic levels of the first to fourth fail detection signals FD<1:4> after the start of a scan operation. The fail detection circuit 23 may detect a second open fail in which a connection between the through vias and the micro bump pads included in the first to fourth signal paths is a fail by detecting the logic levels of the first to fourth fail detection signals FD<1:4> after the start of a scan operation.

The fail detection circuit 23 may detect a first short fail in which the first to fourth signal paths and the ground voltage VSS that is applied to the voltage path are weakly connected by detecting the logic levels of the first to fourth fail detection signals FD<1:4> after the start of a scan operation. The fail detection circuit 23 may detect a second short fail in which the first to fourth signal paths and the ground voltage VSS that is applied to the voltage path are strongly connected by detecting the logic levels of the first to fourth fail detection signals FD<1:4> after the start of a scan operation. The fail detection circuit 23 may detect a third short fail in which the first to fourth signal paths and the source voltage VDD that is applied to the voltage path are strongly connected by detecting the logic levels of the first to fourth fail detection signals FD<1:4> after the start of a scan operation.

FIG. 4 is a block diagram illustrating a construction of the test control circuit 21 according to an embodiment of the present disclosure. The test control circuit 21 may include a buffer circuit (BUF CT) 211, a cycle signal generation circuit (OSC GEN) 212, a scan pulse generation circuit (SP GEN) 213, and a latch signal generation circuit (LAT GEN) 214.

The buffer circuit 211 may generate the down scan signal DNS and the up scan signal UPS, based on the down enable signal DEN and the up enable signal UEN. The buffer circuit 211 may generate the down scan signal DNS by buffering the down enable signal DEN. The buffer circuit 211 may generate the up scan signal UPS by buffering the up enable signal UEN.

The cycle signal generation circuit 212 may generate the cycle signal OSC, based on the down scan signal DNS, the up scan signal UPS, and the first and second test delay signals TD<1:2>. The cycle signal generation circuit 212 may generate the cycle signal OSC including a pulse that is periodically generated, by detecting timing at which the down scan signal DNS and the up scan signal UPS are generated. The cycle signal generation circuit 212 may generate the cycle signal OSC having a pulse width adjusted, based on the first and second test delay signals TD<1:2>. The cycle signal generation circuit 212 may generate the cycle signal OSC that is disabled when a reset signal RST is enabled.

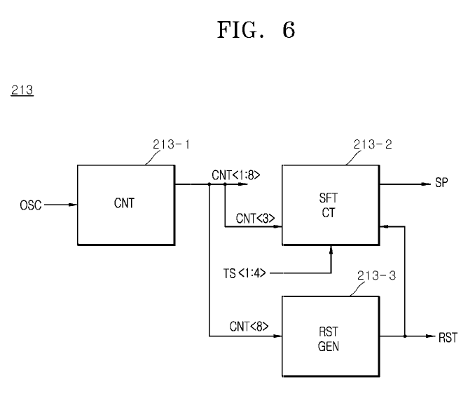

The scan pulse generation circuit 213 may generate the scan pulse SP based on the cycle signal OSC and the first to fourth test selection signals TS<1:4>. The scan pulse generation circuit 213 may generate the scan pulse SP from any one of a plurality of counting signals (CNT<1:8> in FIG. 6) that is generated by counting the cycle signal OSC based on the first to fourth test selection signals TS<1:4>. The scan pulse generation circuit 213 may adjust timing at which the scan pulse SP that latches the logic level of the internal node (ND221 in FIG. 11) that is connected to the signal path is generated, after the start of a scan operation. The scan pulse generation circuit 213 may generate the reset signal RST that is enabled when all of the bits of the plurality of counting signals (CNT<1:8> in FIG. 6) generated by counting the cycle signal OSC are counted.

The latch signal generation circuit 214 may generate the down latch signal DLAT and the up latch signal ULAT, based on the first to third test control signals TC<1:3>, the down scan signal DNS, the up scan signal UPS, the scan pulse SP, the normal latch signal NLAT, and the pad latch signal PLAT. The latch signal generation circuit 214 may generate the down latch signal DLAT based on the scan pulse SP when the first test control signal TC<1> is enabled and the down scan signal DNS is enabled. The latch signal generation circuit 214 may generate the up latch signal ULAT based on the scan pulse SP when the first test control signal TC<1> is enabled and the up scan signal UPS is enabled. The latch signal generation circuit 214 may generate the down latch signal DLAT based on the normal latch signal NLAT when the second test control signal TC<2> is enabled and the down scan signal DNS is enabled. The latch signal generation circuit 214 may generate the up latch signal ULAT based on the normal latch signal NLAT when the second test control signal TC<2> is enabled and the up scan signal UPS is enabled. The latch signal generation circuit 214 may generate the down latch signal DLAT based on the pad latch signal PLAT when the third test control signal TC<3> is enabled and the down scan signal DNS is enabled. The latch signal generation circuit 214 may generate the up latch signal ULAT based on the pad latch signal PLAT when the third test control signal TC<3> is enabled and the up scan signal UPS is enabled.

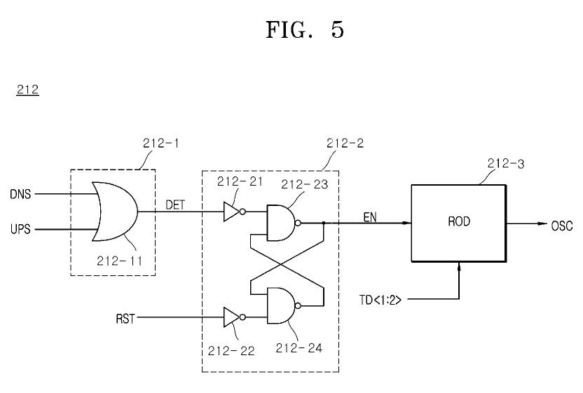

FIG. 5 is a diagram illustrating a construction of the cycle signal generation circuit 212 according to an embodiment of the present disclosure. The cycle signal generation circuit 212 may include a detection signal generation circuit 212-1, an enable signal generation circuit 212-2, and an oscillator (ROD) 212-3.

The detection signal generation circuit 212-1 may be implemented with an OR gate 212-11. The detection signal generation circuit 212-1 may generate a detection signal DET that is enabled when any one of the down scan DNS and the up scan signal UPS is generated. The detection signal generation circuit 212-1 may generate the detection signal DET that is enabled to a logic high level when the down scan DNS is generated at a logic high level. The detection signal generation circuit 212-1 may generate the detection signal DET that is enabled to a logic high level when the up scan signal UPS is generated at a logic high level.

The enable signal generation circuit 212-2 may be implemented with inverters 212-21 and 212-22 and NAND gates 212-23 and 212-24. The enable signal generation circuit 212-2 may generate an enable signal EN based on the detection signal DET and the reset signal RST. The enable signal generation circuit 212-2 may generate the enable signal EN that is enabled to a logic high level when the detection signal DET is enabled to a logic high level. The enable signal generation circuit 212-2 may generate the enable signal EN that is disabled to a logic low level when the reset signal RST is enabled to a logic high level. The enable signal generation circuit 212-2 may generate the enable signal EN that is enabled to a logic high level from timing at which the detection signal DET is enabled to a logic high level to timing at which the reset signal RST is enabled to a logic high level.

The oscillator 212-3 may generate the cycle signal OSC having a pulse width adjusted, based on the enable signal EN and the first and second test delay signals TD<1:2>. The oscillator 212-3 may generate the cycle signal OSC having a short pulse width when the enable signal EN is enabled to a logic high level and the first test delay signal TD<1> is enabled to a logic high level. The oscillator 212-3 may generate the cycle signal OSC having a long pulse width when the enable signal EN is enabled to a logic high level and the second test delay signal TD<2> is enabled to a logic high level. The first and second test delay signals TD<1:2> has been implemented with 2 bits that adjust the pulse width of the cycle signal OSC, but may be implemented with various bits in order to variously adjust the pulse width of the cycle signal OSC.

FIG. 6 is a block diagram illustrating a construction of the scan pulse generation circuit 213 according to an embodiment of the present disclosure. The scan pulse generation circuit 213 may include a counter (CNT) 213-1, a shifting circuit (SFT CT) 213-2, and a reset signal generation circuit (RST GEN) 213-3.

The counter 213-1 may generate the first to eight counting signals CNT<1:8> that are sequentially counted by a pulse to be included in the cycle signal OSC. The counter 213-1 may generate the first to eight counting signals CNT<1:8> that are sequentially counted whenever a pulse included in the cycle signal OSC is generated at a logic high level.

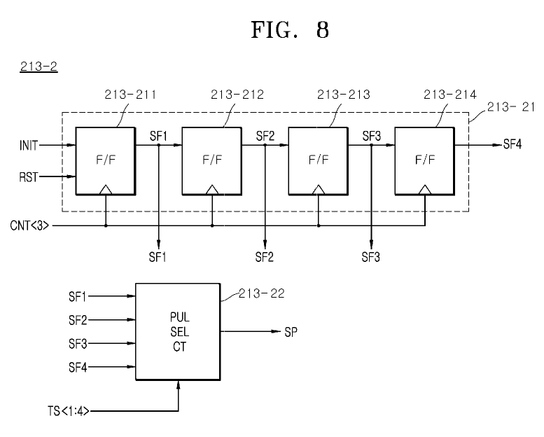

The shifting circuit 213-2 may generate the scan pulse SP based on the first to fourth test selection signals TS<1:4> and the third counting signal CNT<3>. The shifting circuit 213-2 may shift an initialization signal (INIT in FIG. 8) in synchronization with the third counting signal CNT<3>, and may generate the scan pulse SP based on the initialization signal (INIT in FIG. 8) shifted by the first to fourth test selection signals TS<1:4>. The shifting circuit 213-2 has generated the scan pulse SP based on the third counting signal CNT<3>, but may generate the scan pulse SP based on any one of the first to eight counting signals CNT<1:8> according to an embodiment. The shifting circuit 213-2 may adjust timing at which the scan pulse SP is generated by generating the scan pulse SP based on any one of the first to eight counting signals CNT<1:8> after the start of a scan operation.

The reset signal generation circuit 213-3 may generate the reset signal RST based on the eighth counting signal CNT<8>. The reset signal generation circuit 213-3 may generate the reset signal RST that is enabled to a logic high level when the eighth counting signal CNT<8> is generated at a logic high level.

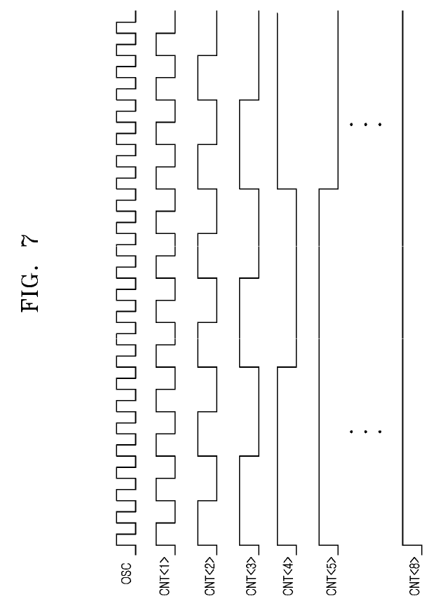

FIG. 7 is a timing diagram for describing an operation of the counter 213 according to an embodiment of the present disclosure.

The counter 213 may generate the first counting signal CNT<1> that is toggled whenever a pulse to be included in the cycle signal OSC is generated at a logic high level.

The counter 213 may generate the second counting signal CNT<2> that is toggled whenever a pulse to be included in the first counting signal CNT<1> is generated at a logic high level.

The counter 213 may generate the third counting signal CNT<3> that is toggled whenever a pulse to be included in the second counting signal CNT<2> is generated at a logic high level.

The counter 213 may generate the fourth counting signal CNT<4> that is toggled whenever a pulse to be included in the third counting signal CNT<3> is generated at a logic high level.

The counter 213 may generate the fifth counting signal CNT<5> that is toggled whenever a pulse to be included in the fourth counting signal CNT<4> is generated at a logic high level.

The counter 213 may generate the sixth counting signal CNT<6> that is toggled whenever a pulse to be included in the fifth counting signal CNT<5> is generated at a logic high level.

The counter 213 may generate the seven counting signal CNT<7> that is toggled whenever a pulse to be included in the sixth counting signal CNT<6> is generated at a logic high level.

The counter 213 may generate the eighth counting signal CNT<8> that is toggled whenever a pulse to be included in the seven the counting signal CNT<7> is generated at a logic high level.

FIG. 8 is a block diagram illustrating a construction of the shifting circuit 213-2 according to an embodiment of the present disclosure. The shifting circuit 213-2 may include a register circuit 213-21 and a pulse selection circuit (PUL SEL CT) 213-22.

The register circuit 213-21 may be implemented with flip-flops (F/F) 213-211, 213-212, 213-213, and 213-214. The flip-flop 213-211 may latch the initialization signal INIT when a pulse included in the third counting signal CNT<3> is generated at a logic high level. The flip-flop 213-211 may output, as a first shifting signal SF1, the initialization signal INIT that is latched when a pulse included in the third counting signal CNT<3> is generated at a logic high level. The flip-flop 213-211 may generate the first shifting signal SF1 that is disabled to a logic low level when the reset signal RST is generated at a logic high level. The initialization signal INIT may be set as a signal that is enabled to a logic high level when a power-up operation is terminated. The power-up operation may be set as a time interval in which the voltage level of an internal voltage (not illustrated) that is generated as an operation of the memory device 17 starts rises according to the voltage level of the source voltage VDD that is supplied from the outside of the memory system 1 and rises to a preset voltage level.

The flip-flop 213-212 may latch the first shifting signal SF1 when a pulse included in the third counting signal CNT<3> is generated at a logic high level. The flip-flop 213-212 may output, as a second shifting signal SF2, the first shifting signal SF1 latched when a pulse included in the third counting signal CNT<3> is generated at a logic high level.

The flip-flop 213-213 may latch the second shifting signal SF2 when a pulse included in the third counting signal CNT<3> is generated at a logic high level. The flip-flop 213-213 may output, as a third shifting signal SF3, the second shifting signal SF2 latched when a pulse included in the third counting signal CNT<3> is generated at a logic high level.

The flip-flop 213-214 may latch the third shifting signal SF3 when a pulse included in the third counting signal CNT<3> is generated at a logic high level. The flip-flop 213-214 may output, as a fourth shifting signal SF4, the third shifting signal SF3 latched when a pulse included in the third counting signal CNT<3> is generated at a logic high level.

The register circuit 213-21 may generate the first to fourth shifting signals SF1, SF2, SF3, and SF4 that are sequentially enabled by shifting the initialization signal INIT when a pulse included in the third counting signal CNT<3> is generated at a logic high level. The register circuit 213-21 may generate the first to fourth shifting signals SF1, SF2, SF3, and SF4 that are disabled to a logic low level when the reset signal RST is generated at a logic high level.

The pulse selection circuit 213-22 may generate the scan pulse SP from any one of the first to fourth shifting signals SF1, SF2, SF3, and SF4 based on the first to fourth test selection signals TS<1:4>. The pulse selection circuit 213-22 may output the first shifting signal SF1 as the scan pulse SP when the first test selection signal TS<1> is enabled to a logic high level. The pulse selection circuit 213-22 may output the second shifting signal SF2 as the scan pulse SP when the second test selection signal TS<2> is enabled to a logic high level. The pulse selection circuit 213-22 may output the third shifting signal SF3 as the scan pulse SP when the third test selection signal TS<3> is enabled to a logic high level. The pulse selection circuit 213-22 may output the fourth shifting signal SF4 as the scan pulse SP when the fourth test selection signal TS<4> is enabled to a logic high level. The first to fourth test selection signals TS<1:4> have included 4 bits in order to generate the scan pulse SP from any one of the first to fourth shifting signals SF1, SF2, SF3, and SF4, but may include various bits in order to generate the scan pulse SP from a plurality of shifting signals.

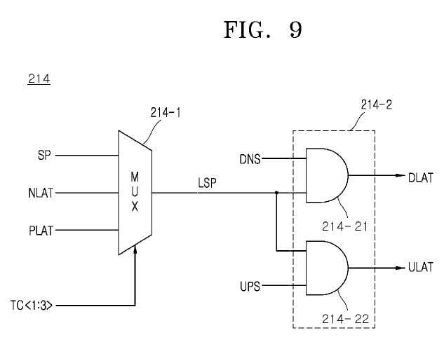

FIG. 9 is a diagram illustrating a construction of the latch signal generation circuit 214 according to an embodiment of the present disclosure. The latch signal generation circuit 214 may include a latch selection pulse generation circuit (MUX) 214-1 and a logic circuit 214-2.

The latch selection pulse generation circuit 214-1 may generate a latch selection pulse LSP, based on the first to third test control signals TC<1:3>, the scan pulse SP, the normal latch signal NLAT, and the pad latch signal PLAT. The latch selection pulse generation circuit 214-1 may output the scan pulse SP as the latch selection pulse LSP when the first test control signal TC<1> is enabled. The latch selection pulse generation circuit 214-1 may output the normal latch signal NLAT as the latch selection pulse LSP when the second test control signal TC<2> is enabled. The latch selection pulse generation circuit 214-1 may output the pad latch signal PLAT as the latch selection pulse LSP when the third test control signal TC<3> is enabled.

The logic circuit 214-2 may be implemented with AND gates 214-21 and 214-22. The logic circuit 214-2 may generate the down latch signal DLAT and the up latch signal ULAT, based on the down scan signal DNS, the up scan signal UPS, and the latch selection pulse LSP. The logic circuit 214-2 may generate the down latch signal DLAT that is enabled to a logic high level when the down scan signal DNS is enabled to a logic high level and the latch selection pulse LSP is enabled to a logic high level. The logic circuit 214-2 may generate the up latch signal ULAT that is enabled to a logic high level when the up scan signal UPS is enabled to a logic high level and the latch selection pulse LSP is enabled to a logic high level.

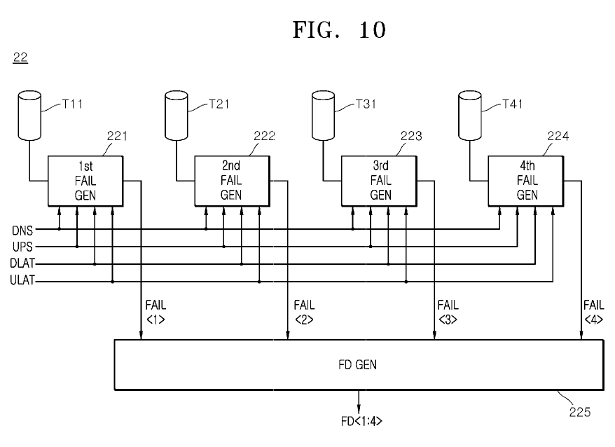

FIG. 10 is a block diagram illustrating a construction of the base test circuit 22 according to an embodiment of the present disclosure. The base test circuit 22 may include a first fail signal generation circuit (1^{st} FAIL GEN) 221, a second fail signal generation circuit (2^{nd} FAIL GEN) 222, a third fail signal generation circuit (3^{rd} FAIL GEN) 223, a fourth fail signal generation circuit (4^{th} FAIL GEN) 224, and a fail detection signal generation circuit (FD GEN) 225.

The first fail signal generation circuit 221 may be electrically connected to the through via T11, that is, the first signal path. The first fail signal generation circuit 221 may generate a first fail signal FAIL<1>, based on the down scan signal DNS, the up scan signal UPS, the down latch signal DLAT, and the up latch signal ULAT. The first fail signal generation circuit 221 may drive the through via T11 through an NMOS transistor (221-13 in FIG. 11) when the down scan signal DNS is enabled. The first fail signal generation circuit 221 may latch the logic level of the internal node (ND221 in FIG. 11) that is connected to the through via T11 driven through an NMOS transistor (221-23 in FIG. 11) when the down latch signal DLAT is enabled. The first fail signal generation circuit 221 may drive the through via T11 through a PMOS transistor (221-12 in FIG. 11) when the up scan signal UPS is enabled. The first fail signal generation circuit 221 may latch the logic level of the internal node (ND221 in FIG. 11) that is connected to the through via T11 driven through the PMOS transistor (221-12 in FIG. 11) when the up latch signal ULAT is enabled. The first fail signal generation circuit 221 may generate the first fail signal FAIL<1> based on the logic level of the internal node (ND221 in FIG. 11) that is connected to the through via T11.

The second fail signal generation circuit 222 may be electrically connected to the through via T21, that is, the second signal path. The second fail signal generation circuit 222 may generate a second fail signal FAIL<2>, based on the down scan signal DNS, the up scan signal UPS, the down latch signal DLAT, and the up latch signal ULAT. The second fail signal generation circuit 222 may drive the through via T21 through an NMOS transistor (not illustrated) when the down scan signal DNS is enabled. The second fail signal generation circuit 222 may latch the logic level of an internal node (not illustrated) that is connected to the through via T21 through the NMOS transistor (not illustrated) driven when the down latch signal DLAT is enabled. The second fail signal generation circuit 222 may drive the through via T21 through a PMOS transistor (not illustrated) when the up scan signal UPS is enabled. The second fail signal generation circuit 222 may latch the logic level of the internal node (not illustrated) that is connected to the through via T21 driven through the PMOS transistor (not illustrated) when the up latch signal ULAT is enabled. The second fail signal generation circuit 222 may generate the second fail signal FAIL<2> based on the logic level of the internal node (not illustrated) that is connected to the through via T21.

The third fail signal generation circuit 223 may be electrically connected to the through via T31, that is, the third signal path. The third fail signal generation circuit 223 may generate a third fail signal FAIL<3>, based on the down scan signal DNS, the up scan signal UPS, the down latch signal DLAT, and the up latch signal ULAT. The third fail signal generation circuit 223 may drive the through via T31 through an NMOS transistor (not illustrated) when the down scan signal DNS is enabled. The third fail signal generation circuit 223 may latch the logic level of an internal node (not illustrated) that is connected to the through via T31 driven through the NMOS transistor (not illustrated) when the down latch signal DLAT is enabled. The third fail signal generation circuit 223 may drive the through via T31 through a PMOS transistor (not illustrated) when the up scan signal UPS is enabled. The third fail signal generation circuit 223 may latch the logic level of the internal node (not illustrated) that is connected to the through via T31 driven through the PMOS transistor (not illustrated) when the up latch signal ULAT is enabled. The third fail signal generation circuit 223 may generate the third fail signal FAIL<3> based on the logic level of the internal node (not illustrated) that is connected to the through via T31.

The fourth fail signal generation circuit 224 may be electrically connected to the through via T41, that is, the fourth signal path. The fourth fail signal generation circuit 224 may generate a fourth fail signal FAIL<4>, based on the down scan signal DNS, the up scan signal UPS, the down latch signal DLAT, and the up latch signal ULAT. The fourth fail signal generation circuit 224 may drive the through via T41 through an NMOS transistor (not illustrated) when the down scan signal DNS is enabled. The fourth fail signal generation circuit 224 may latch the logic level of an internal node (not illustrated) that is connected to the through via T41 driven through the NMOS transistor (not illustrated) when the down latch signal DLAT is enabled. The fourth fail signal generation circuit 224 may drive the through via T41 through a PMOS transistor (not illustrated) when the up scan signal UPS is enabled. The fourth fail signal generation circuit 224 may latch the logic level of the internal node (not illustrated) that is connected to the through via T41 driven through the PMOS transistor (not illustrated) when the up latch signal ULAT is enabled. The fourth fail signal generation circuit 224 may generate the fourth fail signal FAIL<4> based on the logic level of the internal node (not illustrated) that is connected to the through via T41.

The fail detection signal generation circuit 225 may generate the first to fourth fail detection signals FD<1:4> based on the first to fourth fail signals FAIL<1:4>. The fail detection signal generation circuit 225 may latch the first to fourth fail signals FAIL<1:4>. The fail detection signal generation circuit 225 may output the latched first to fourth fail signals FAIL<1:4> as the first to fourth fail detection signals FD<1:4>.

FIG. 11 is a diagram illustrating a construction of the first fail signal generation circuit 221 according to an embodiment of the present disclosure. The first fail signal generation circuit 221 may include a first base driving circuit 221-1 and a first storage circuit 221-2.

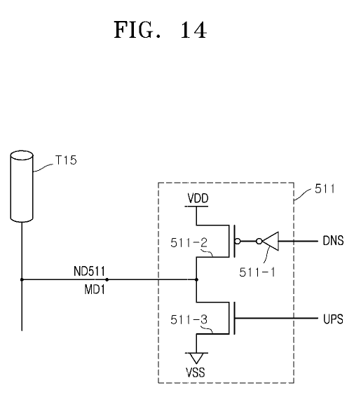

The first base driving circuit 221-1 may include an inverter 221-11, the PMOS transistor 221-12, and the NMOS transistor 221-13. The inverter 221-11 may output the up scan signal UPS by inverting the up scan signal UPS. The PMOS transistor 221-12 is connected between the source voltage VDD and the node ND221, and may generate first base data BD1 at a logic high level by driving the node ND221 to the voltage level of the source voltage VDD when the output signal of the inverter 221-11 is at a logic low level. The NMOS transistor 221-13 is connected between the node ND221 and the ground voltage VSS, and may generate the first base data BD1 at a logic low level by driving the node ND221 to the voltage level of the ground voltage VSS when the down scan signal DNS is a logic high level. The PMOS transistor 221-12 of the first base driving circuit 221-1 may be set to have a greater driving force than an NMOS transistor (511-3 in FIG. 14) of a first path driving circuit 511. Accordingly, when a fail does not occur in the through vias T11, T12, T13, and T14, that is, the first signal path, the first base driving circuit 221-1 may drive the through vias T11, T12, T13, and T14 to the voltage level of the source voltage VDD.

The first storage circuit 221-2 may include a first latch (1^{st} LATCH) 221-21, a second latch (2^{nd} LATCH) 221-22, and the AND gate 221-23.

The first latch 221-21 may generate first latch data LD1 at a logic high level when a power-up operation is terminated. The first latch 221-21 may latch the first base data BD1 when the down latch signal DLAT is enabled to a logic high level. The first latch 221-21 may output the latched first base data BD1 as the first latch data LD1.

The second latch 221-22 may generate second latch data LD2 at a logic high level when a power-up operation is terminated. The second latch 221-22 may latch the first base data BD1 when the up latch signal ULAT is enabled to a logic high level. The second latch 221-22 may output the latched first base data BD1 as the second latch data LD2.

The AND gate 221-23 may generate the first fail signal FAIL<1> based on the logic levels of the first latch data LD1 and the second latch data LD2. The AND gate 221-23 may generate the first fail signal FAIL<1> at a logic high level when the first latch data LD1 is at a logic high level and the second latch data LD2 is a logic high level. The AND gate 221-23 may generate the first fail signal FAIL<1> at a logic low level when at least any one of the first latch data LD1 and the second latch data LD2 is at a logic low level.

The second to fourth fail signal generation circuits 222, 223, and 224 illustrated in FIG. 10 are electrically connected to the through vias T21, T31, and T41, merely generate the second to fourth fail signals FAIL<2:4>, respectively, and are each implemented with the same circuits as the first fail signal generation circuit 221 illustrated in FIG. 11 and perform the same operation as the first fail signal generation circuit 221. Accordingly, detailed descriptions of the second to fourth fail signal generation circuits 222, 223, and 224 are omitted.

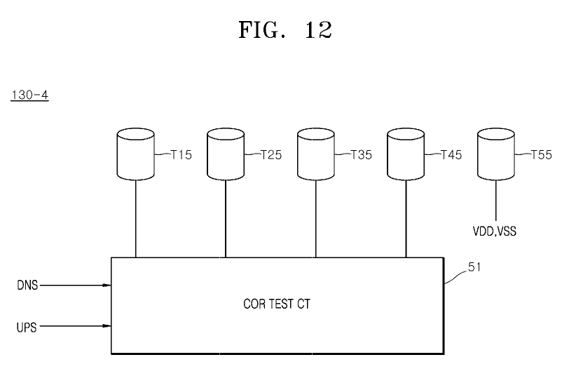

FIG. 12 is a block diagram illustrating a construction of the fourth core chip 130-4 according to an embodiment of the present disclosure. The fourth core chip 130-4 may include the through vias T15, T25, T35, T45, and T55 and the core test circuit 51.

The core test circuit 51 may receive the down scan signal DNS and the up scan signal UPS from the base chip 120. The down scan signal DNS and the up scan signal UPS may be input from the base chip 120 to the core test circuit 51 through separate through vias except the through vias T11, T12, T13, T14, T21, T22, T23, T24, T31, T32, T33, T34, T41, T42, T43, T44, T51, T52, T53, and T54.

The core test circuit 51 may be electrically connected to the through vias T15, T25, T35, and T45. The core test circuit 51 may drive the through vias T15, T25, T35, and T45 through any one of a PMOS transistor and an NMOS transistor after the start of a scan operation. The core test circuit 51 may drive the through vias T14, T24, T34, and T44 through any one of the PMOS transistor and the NMOS transistor based on the down scan signal DNS and the up scan signal UPS after the start of a scan operation. The core test circuit 51 may drive the through vias T15, T25, T35, and T45 to the source voltage (VDD in FIG. 14) through the PMOS transistor when the down scan signal DNS is enabled after the start of a down scan operation of a scan operation. The core test circuit 51 may drive the through vias T15, T25, T35, and T45 to the ground voltage (VSS in FIG. 14) through the NMOS transistor when the up scan signal UPS is enabled after the start of an up scan operation of a scan operation.

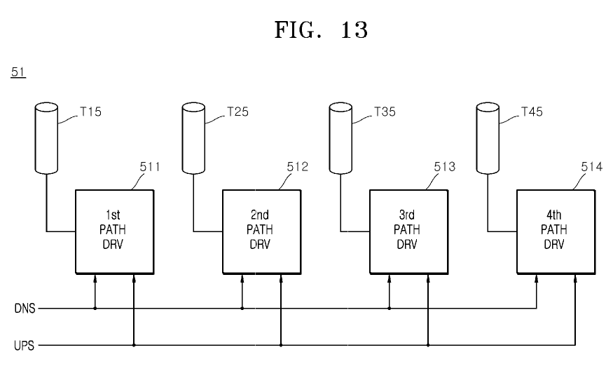

FIG. 13 is a block diagram illustrating a construction of the core test circuit 51 according to an embodiment of the present disclosure. The core test circuit 51 may include a first path driving circuit (1^{st} PATH DRV) 511, a second path driving circuit (2^{nd} PATH DRV) 512, a third path driving circuit (3^{rd} PATH DRV) 513, and a fourth path driving circuit (4^{th} PATH DRV) 514.

The first path driving circuit 511 may be electrically connected to the through via T15, that is, the first signal path. The first path driving circuit 511 may drive the through via T15 based on the down scan signal DNS and the up scan signal UPS. The first path driving circuit 511 may drive the through via T15 through a PMOS transistor (511-2 in FIG. 14) when the down scan signal DNS is enabled. The first path driving circuit 511 may drive the through via T15 through an NMOS transistor (511-3 in FIG. 14) when the up scan signal UPS is enabled.

The second path driving circuit 512 may be electrically connected to the through via T25, that is, the second signal path. The second path driving circuit 512 may drive the through via T25 based on the down scan signal DNS and the up scan signal UPS. The second path driving circuit 512 may drive the through via T25 through a PMOS transistor (not illustrated) when the down scan signal DNS is enabled. The second path driving circuit 512 may drive the through via T25 through an NMOS transistor (not illustrated) when the up scan signal UPS is enabled.

The third path driving circuit 513 may be electrically connected to the through via T35, that is, the third signal path. The third path driving circuit 513 may drive the through via T35 based on the down scan signal DNS and the up scan signal UPS. The third path driving circuit 513 may drive the through via T35 through a PMOS transistor (not illustrated) when the down scan signal DNS is enabled. The third path driving circuit 513 may drive the through via T35 through an NMOS transistor (not illustrated) when the up scan signal UPS is enabled.

The fourth path driving circuit 514 may be electrically connected to the through via T45, that is, the fourth signal path. The fourth path driving circuit 514 may drive the through via T45 based on the down scan signal DNS and the up scan signal UPS. The fourth path driving circuit 514 may drive the through via T45 through a PMOS transistor (not illustrated) when the down scan signal DNS is enabled. The fourth path driving circuit 514 may drive the through via T45 through an NMOS transistor (not illustrated) when the up scan signal UPS is enabled.

FIG. 14 is a circuit diagram illustrating the construction of the first path driving circuit 511 according to an embodiment of the present disclosure.

The first path driving circuit 511 may include an inverter 511-1, the PMOS transistor 511-2, and the NMOS transistor 511-3. The inverter 511-1 may output the down scan signal DNS by inverting the down scan signal DNS. The PMOS transistor 511-2 is connected between the source voltage VDD and a node ND511, and may generate first memory data MD1 at a logic high level by driving the node ND511 to the voltage level of the source voltage VDD when the output signal of the inverter 511-1 is at a logic low level. The NMOS transistor 511-3 is connected between the node ND511 and the ground voltage VSS, and may generate the first memory data MD1 at a logic low level by driving the node ND511 to the voltage level of the ground voltage VSS when the up scan signal UPS is a logic high level. The PMOS transistor 511-2 of the first path driving circuit 511 may be set to have a greater driving force than the NMOS transistor (221-13 in FIG. 11) of the first fail signal generation circuit 221. Accordingly, the first path driving circuit 511 may drive the through vias T11, T12, T13, and T14 to the voltage level of the source voltage VDD when a fail does not occur in the through vias T11, T12, T13, and T14, that is, the first signal path.

The second to fourth path driving circuits 512, 513, and 514 illustrated in FIG. 13 are electrically connected to the through vias T25, T35, and T45, merely drive the through vias T25, T35, and T45, respectively, and are each implemented with the same circuits as the first path driving circuit 511 illustrated in FIG. 14 and perform the same operation as the first path driving circuit 511. Accordingly, detailed descriptions of the second to fourth path driving circuits 512, 513, and 514 are omitted.

An operation of detecting a connection fail between the signal paths of the memory device 17 according to an embodiment of the present disclosure is described with reference to FIG. 15. In this case, an operation of detecting the first open fail in which the first signal path is disconnected after the start of a down scan operation of a scan operation is described as an example as follows.

The test control circuit 21 generates the down scan signal DNS that is enabled to a logic high level when the down scan enable signal DEN is enabled.

The first path driving circuit 511 drives the through via T15 of the first signal path to the voltage level of the source voltage VDD through the PMOS transistor 511-2 when the down scan signal DNS is enabled to a logic high level.

The first base driving circuit 221-1 drives the through via T11 of the first signal path to the voltage level of the ground voltage VSS through the NMOS transistor 221-13 when the down scan signal DNS is enabled to a logic high level. At this time, when the through via T15 of the first signal path and the through via T11 of the first signal path are disconnected (OPEN), the node ND221 that is connected to the through via T11 is driven to the voltage level of the ground voltage VSS, and thus the first base data BD1 are generated at a logic low level.

In this case, as in the graph of FIG. 15, a case in which the node ND221 is driven to the voltage level of the source voltage VDD at timing X means a case in which a fail does not occur in the first signal path (NORMAL). A case in which the node ND221 is driven to the voltage level of the ground voltage VSS at timing X means a case in which the first open fail OPEN1 occurs.

The first storage circuit 221-2 generates the first fail signal FAIL<1> at a logic low level by latching the first base data BD1 at timing X at which the down latch signal DLAT is enabled to a logic high level. Timing X means timing set after the start of a scan operation. In a conventional technology, timing X may be set as timing at which the normal latch signal NLAT is enabled after the start of a scan operation.

The base test circuit 22 generates the first fail detection signal FD<1> at a logic low level from the first fail signal FAIL<1> at the logic low level.

The fail detection circuit 23 detects the first open fail OPEN1 in which the first signal path is disconnected when the first fail detection signal FD<1> is generated at a logic low level after the start of a scan operation.

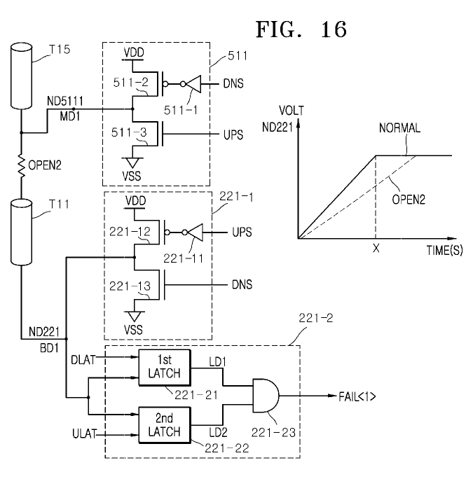

An operation of detecting a connection fail between the signal paths of the memory device 17 according to an embodiment of the present disclosure is described with reference to FIG. 16. In this case, an operation of detecting the second open fail in which the through via included in the first signal path and the micro bump are weakly connected after the start of a down scan operation of a scan operation is described as an example as follows. The weak connection between the through via and the micro bump included in the first signal path means that a space is formed between the through via and the micro bump, causing the through via and the micro bump to be electrically incompletely connected.

The test control circuit 21 generates the down scan signal DNS that is enabled to a logic high level when the down scan enable signal DEN is enabled.

The first path driving circuit 511 drives the through via T15 of the first signal path to the voltage level of the source voltage VDD through the PMOS transistor 511-2 when the down scan signal DNS is enabled to a logic high level.

The first base driving circuit 221-1 drives the through via T11 of the first signal path to the voltage level of the ground voltage VSS through the NMOS transistor 221-13 when the down scan signal DNS is enabled to a logic high level. At this time, when the through via T15 included in the first signal path and the micro bump are weakly connected, the node ND221 connected to the through via T11 is slowly driven to the voltage level of the source voltage VDD, and thus the first base data BD1 is generated at a logic low level.

In this case, as in the graph of FIG. 16, a case in which the node ND221 is driven to the voltage level of the source voltage VDD at timing X means a case in which a fail does not occur in the first signal path (NORMAL). A case in which the node ND221 is slowly driven to the voltage level of the source voltage VDD at timing X means a case in which the second open fail OPEN2 occurs.

The first storage circuit 221-2 generates the first fail signal FAIL<1> at a logic low level by latching the first base data BD1 at timing X at which the down latch signal DLAT is enabled to a logic high level. Timing X means timing set after the start of a scan operation. In a comparative example of technology, timing X may be set as timing at which the normal latch signal NLAT is enabled after the start of a scan operation.

The base test circuit 22 generates the first fail detection signal FD<1> at a logic low level from the first fail signal FAIL<1> at the logic low level.

The fail detection circuit 23 detects the second open fail OPEN2 in which the through via included in the first signal path and the micro bump are weakly connected when the first fail detection signal FD<1> is generated at a logic low level after the start of a scan operation.

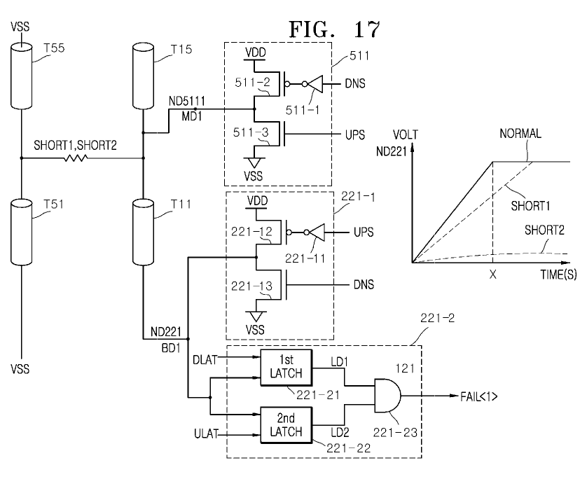

An operation of detecting a connection fail between the signal paths of the memory device 17 according to an embodiment of the present disclosure is described with reference to FIG. 17. In this case, an operation of detecting the first short fail in which the first signal path and the ground voltage VSS applied to the voltage path are weakly connected by continuously performing the down scan operation and up scan operation of a scan operation is described as an example as follows. The weak connection between the first signal path and the ground voltage VSS applied to the voltage path means that a space is formed between the through via included in the first signal path and the through via included in the voltage path, causing the through via and the through via to be electrically incompletely connected.

The test control circuit 21 generates the down scan signal DNS that is enabled to a logic high level when the down scan enable signal DEN is enabled.

The first path driving circuit 511 drives the through via T15 of the first signal path to the voltage level of the source voltage VDD through the PMOS transistor 511-2 when the down scan signal DNS is enabled to a logic high level.

The first base driving circuit 221-1 drives the through via T11 of the first signal path to the voltage level of the ground voltage VSS through the NMOS transistor 221-13 when the down scan signal DNS is enabled to a logic high level. At this time, when the first signal path and the ground voltage VSS applied to the voltage path are weakly connected, the node ND221 that is connected to the through via T11 is slowly driven to the voltage level of the source voltage VDD, and thus the first base data BD1 is generated at a logic low level.

The test control circuit 21 generates the up scan signal UPS that is enabled to a logic high level when the up scan enable signal UEN is enabled.

The first path driving circuit 511 drives the through via T15 of the first signal path to the voltage level of the ground voltage VSS through the NMOS transistor 511-3 when the up scan signal UPS is enabled to a logic high level.

The first base driving circuit 221-1 drives the through via T11 of the first signal path to the voltage level of the source voltage VDD through the PMOS transistor 221-12 when the up scan signal UPS is enabled to a logic high level. At this time, when the first signal path and the ground voltage VSS applied to the voltage path are weakly connected, the node ND221 that is connected to the through via T11 is slowly driven to the voltage level of the source voltage VDD, and thus the first base data BD1 is generated at a logic low level.

In this case, as in the graph of FIG. 17, a case in which the node ND221 is driven to the voltage level of the source voltage VDD at timing X means a case in which a fail does not occur in the first signal path (NORMAL). A case in which the node ND221 is slowly driven to the voltage level of the source voltage VDD at timing X means a case in which the first short fail SHORT1 occurs.

The first storage circuit 221-2 generates a first latch data LD<1> at a logic low level by latching the first base data BD1 at timing X at which the down latch signal DLAT is enabled to a logic high level after the start of a down scan operation, and generates a second latch data LD<2> at a logic low level by latching the first base data BD1 at timing X at which the up latch signal ULAT is enabled to a logic high level after the start of an up scan operation. The first storage circuit 221-2 generates the first fail signal FAIL<1> at a logic low level based on the first latch data LD<1> at the logic low level and the second latch data LD<2> at the logic low level. Timing X means timing set after the start of a scan operation. In a comparative example of technology, timing X may be set as timing at which the normal latch signal NLAT is enabled after the start of a scan operation.

The base test circuit 22 generates the first fail detection signal FD<1> at a logic low level from the first fail signal FAIL<1> at the logic low level.

The fail detection circuit 23 detects the first short fail SHORT1 in which the first signal path and the ground voltage VSS applied to the voltage path are weakly connected if the first fail detection signal FD<1> is generated at a logic low level when the down scan operation and up scan operation of a scan operation are continuously performed.

An operation of detecting a connection fail between the signal paths of the memory device 17 according to an embodiment of the present disclosure is described with reference to FIG. 17. In this case, an operation of detecting the second short fail in which the first signal path and the ground voltage VSS applied to the voltage path are strongly connected by continuously performing the down scan operation and up scan operation of the scan operation is described as an example as follows. The strong connection between the first signal path and the ground voltage VSS applied the voltage path means that the through via included in the first signal path and the ground voltage VSS are electrically connected.

The test control circuit 21 generates the down scan signal DNS that is enabled to a logic high level when the down scan enable signal DEN is enabled.

The first path driving circuit 511 drives the through via T15 of the first signal path to the voltage level of the source voltage VDD through the PMOS transistor 511-2 when the down scan signal DNS is enabled to a logic high level.

The first base driving circuit 221-1 drives the through via T11 of the first signal path to the voltage level of the ground voltage VSS through the NMOS transistor 221-13 when the down scan signal DNS is enabled to a logic high level. At this time, if the first signal path and the ground voltage VSS applied to the voltage path are strongly connected, the node ND221 that is connected to the through via T11 is driven to the voltage level of the ground voltage VSS, and thus the first base data BD1 is generated at a logic low level.

The test control circuit 21 generates the up scan signal UPS that is enabled to a logic high level when the up scan enable signal UEN is enabled.

The first path driving circuit 511 drives the through via T15 of the first signal path to the voltage level of the ground voltage VSS through the NMOS transistor 511-3 when the up scan signal UPS is enabled to a logic high level.

The first base driving circuit 221-1 drives the through via T11 of the first signal path to the voltage level of the source voltage VDD through the PMOS transistor 221-12 when the up scan signal UPS is enabled to a logic high level. At this time, if the first signal path and the ground voltage VSS applied to the voltage path are strongly connected, the node ND221 that is connected to the through via T11 is driven to the voltage level of the ground voltage VSS, and thus the first base data BD1 is generated at a logic low level.

In this case, as in the graph of FIG. 17, a case in which the node ND221 is driven to the voltage level of the source voltage VDD at timing X means a case in which a fail does not occur in the first signal path (NORMAL). A case in which the node ND221 is driven to the voltage level of the ground voltage VSS at timing X means a case in which the second short fail SHORT2 occurs.

The first storage circuit 221-2 generates the first latch data LD<1> at a logic low level by latching the first base data BD1 at timing X at which the down latch signal DLAT is enabled to a logic high level after the start of a down scan operation, and generates the second latch data LD<2> at a logic low level by latching the first base data BD1 at timing X at which the up latch signal ULAT is enabled to a logic high level after the start of an up scan operation. The first storage circuit 221-2 generates the first fail signal FAIL<1> at a logic low level based on the first latch data LD<1> at the logic low level and the second latch data LD<2> at the logic low level. Timing X means timing set after the start of a scan operation. In a comparative example of technology, timing X may be set as timing at which the normal latch signal NLAT is enabled after the start of a scan operation.

The base test circuit 22 generates the first fail detection signal FD<1> at a logic low level from the first fail signal FAIL<1> at the logic low level.

The fail detection circuit 23 detects the second short fail SHORT2 in which the first signal path and the ground voltage VSS applied to the voltage path are strongly connected if the first fail detection signal FD<1> is generated at a logic low level when the down scan operation and up scan operation of a scan operation are continuously performed.

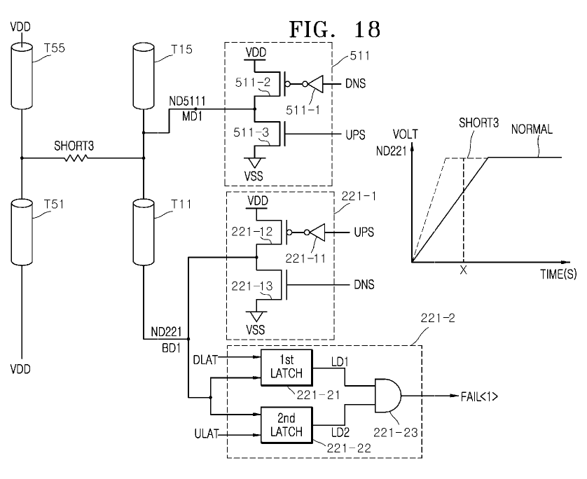

An operation of detecting a connection fail between the signal paths of the memory device 17 according to an embodiment of the present disclosure is described with reference to FIG. 18. In this case, an operation of detecting the third short fail in which the first signal path and the source voltage VDD that is applied to the voltage path are strongly connected because the down scan operation and up scan operation of a scan operation are continuously performed is described as an example as follows. The strong connection between the first signal path and the source voltage VDD applied the voltage path means that the through via included in the first signal path and the source voltage VDD are electrically connected.

The test control circuit 21 generates the down scan signal DNS that is enabled to a logic high level when the down scan enable signal DEN is enabled.

The first path driving circuit 511 drives the through via T15 of the first signal path to the voltage level of the source voltage VDD through the PMOS transistor 511-2 when the down scan signal DNS is enabled to a logic high level.

The first base driving circuit 221-1 drives the through via T11 of the first signal path to the voltage level of the ground voltage VSS through the NMOS transistor 221-13 when the down scan signal DNS is enabled to a logic high level. At this time, if the first signal path and the source voltage VDD that is applied to the voltage path are strongly connected, the node ND221 that is connected to the through via T11 is driven to the voltage level of the source voltage VDD, and thus the first base data BD1 is generated at a logic high level.

The test control circuit 21 generates the up scan signal UPS that is enabled to a logic high level when the up scan enable signal UEN is enabled.

The first path driving circuit 511 drives the through via T15 of the first signal path to the voltage level of the ground voltage VSS through the NMOS transistor 511-3 when the up scan signal UPS is enabled to a logic high level.

The first base driving circuit 221-1 drives the through via T11 of the first signal path to the voltage level of the source voltage VDD through the PMOS transistor 221-12 when the up scan signal UPS is enabled to a logic high level. At this time, if the first signal path and the source voltage VDD that is applied to the voltage path are strongly connected, the node ND221 that is connected to the through via T11 is driven to the voltage level of the source voltage VDD, and thus the first base data BD1 is generated at a logic high level.

In this case, as in the graph of FIG. 18, a case in which the node ND221 is driven to the voltage level of the source voltage VDD at timing X means a case in which a fail does not occur in the first signal path (NORMAL). A case in which the node ND221 is driven to the voltage level of the source voltage VDD at timing X means a case in which the third short fail SHORT3 occurs.

The first storage circuit 221-2 generates the first latch data LD<1> at a logic high level by latching the first base data BD1 at timing X at which the down latch signal DLAT is enabled to a logic high level after the start of a down scan operation, and generates the second latch data LD<2> at a logic high level by latching the first base data BD1 at timing X at which the up latch signal ULAT is enabled to a logic high level after the start of an up scan operation. The first storage circuit 221-2 generates the first fail signal FAIL<1> at a logic high level based on the first latch data LD<1> at the logic high level and the second latch data LD<2> at the logic high level. Timing X means timing set after the start of a scan operation. In a comparative example of technology, timing X may be set as timing earlier than timing at which the normal latch signal NLAT is enabled after the start of a scan operation.

The base test circuit 22 generates the first fail detection signal FD<1> at a logic high level from the first fail signal FAIL<1> at the logic high level.

The fail detection circuit 23 detects the third short fail SHORT3 in which the first signal path and the source voltage VDD that is applied to the voltage path are strongly connected if the first fail detection signal FD<1> is generated at a logic high level when the down scan operation and up scan operation of a scan operation are continuously performed.

As described above, the memory device 17 according to an embodiment of the present disclosure can detect various connection fails between a plurality of signal paths by adjusting timing at which the logic level of the internal node that is connected to the plurality of signal paths is latched. The memory device 17 can detect various connection fails in a plurality of signal paths and the voltage path by adjusting timing at which the logic level of the internal node that is connected to the plurality of signal paths is latched.

The embodiments of the present disclosure have been described so far. A person having ordinary knowledge in the art to which the disclosure pertains will understand that the embodiments may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A memory device comprising:
a core chip vertically stacked on a base chip through a portion of a signal path located between the core chip and the base chip, the core chip spaced apart from the base chip with the portion of the signal path,
wherein the base chip and the core chip drive the signal path after a start of a scan operation and detect a connection fail of the signal path based on a logic level at which an internal node that is connected to the signal path is driven, and
wherein the base chip adjusts a timing at which the logic level of the internal node is latched.

2. The memory device of claim 1, wherein:
the signal path comprises a first through via included in the core chip, a micro bump pad, and a second through via included in the base chip,
the first through via and the second through via are electrically connected through the micro bump pad,
the first through via is driven to a source voltage through a P-type Metal-Oxide-Semiconductor (PMOS) transistor after the start of the scan operation, and
the second through via is driven to a ground voltage through an N-type Metal-Oxide-Semiconductor (NMOS) transistor after the start of the scan operation.

3. The memory device of claim 1, wherein the base chip detects a first open fail in which the signal path is disconnected when the logic level of the internal node is a level of a ground voltage after a start of a down scan operation of the scan operation.

4. The memory device of claim 1, wherein the base chip detects a second open fail that is a connection fail between a through via and a micro bump included in the signal path when the logic level of the internal node does not equal or exceed a level of a source voltage after a start of a down scan operation of the scan operation.

5. The memory device of claim 1, wherein the base chip comprises:
a test control circuit configured to generate a down scan signal and an up scan signal from a down enable signal and an up enable signal that perform the scan operation and configured to generate a down latch signal and an up latch signal that latch the logic level of the internal node based on a test delay signal and a test selection signal;
a base test circuit configured to drive the signal path based on the down scan signal and the up scan signal and configured to generate a fail detection signal based on the logic level of the internal node when the down latch signal and the up latch signal are generated; and
a fail detection circuit configured to detect the connection fail of the signal path based on the fail detection signal.

6. The memory device of claim 5, wherein the test control circuit comprises:
a buffer circuit configured to generate the down scan signal and the up scan signal by respectively buffering the down enable signal and the up enable signal;
a cycle signal generation circuit configured to generate a cycle signal comprising a pulse that is periodically generated by detecting timing at which the down scan operation and the up scan signal are generated and configured to adjust a pulse width of the cycle signal based on the test delay signal;
a scan pulse generation circuit configured to generate a scan pulse from any one of a plurality of counting signals that is generated by counting the cycle signal based on the test selection signal; and
a latch signal generation circuit configured to generate the down latch signal based on the scan pulse when the down scan signal is enabled and configured to generate the up latch signal based on the scan pulse when the up scan signal is enabled.

7. The memory device of claim 6, wherein the cycle signal generation circuit comprises:
a detection signal generation circuit configured to generate a detection signal that is enabled when any one of the down scan operation and the up scan signal is generated;
an enable signal generation circuit configured to generate an enable signal that is enabled from timing at which the detection signal is enabled to timing at which a reset signal is enabled; and
an oscillator configured to generate the cycle signal including the pulse width adjusted based on the enable signal and the test delay signal.

8. The memory device of claim 6, wherein the scan pulse generation circuit comprises:
a counter configured to generate the plurality of counting signals that is counted by the pulse included in the cycle signal;
a shifting circuit configured to generate the scan pulse from any one of the plurality of counting signals based on the test selection signal; and
a reset signal generation circuit configured to generate a reset signal that is enabled when all of the plurality of counting signals are counted.

9. The memory device of claim 6, wherein the latch signal generation circuit comprises:
a latch selection pulse generation circuit configured to output the scan pulse as a latch selection pulse based on a test control signal; and
a logic circuit configured to generate the down latch signal based on the latch selection pulse when the down scan signal is enabled and configured to generate the up latch signal based on the latch selection pulse when the up scan signal is enabled.

10. A memory device comprising:
a core chip vertically stacked on a base chip through a first portion of a signal path located between the core chip and the base chip and a second portion of a voltage path located between the core chip and the base chip, the core chip spaced apart from the base chip by the first and second portions of the signal and voltage paths, respectively,
wherein the base chip and the core chip drive the signal path after a start of a scan operation, detect a connection fail of the signal path and a connection fail of the signal path and the voltage path based on a logic level at which an internal node that is connected to the signal path is driven, and
wherein the base chip adjusts a timing at which the logic level of the internal node is latched.

11. The memory device of claim 10, wherein:
the signal path is a path along which signals that control an operation of the core chip are input and output, and
the voltage path is a path along which a source voltage and a ground voltage supplied to the core chip are applied.

12. The memory device of claim 10, wherein:
the signal path comprises a first through via included in the core chip, a micro bump pad, and a second through via included in the base chip, and
the first through via and the second through via are electrically connected through the micro bump pad.

13. The memory device of claim 12, wherein:
the first through via is driven to a source voltage through a first P-type Metal-Oxide-Semiconductor (PMOS) transistor after a start of a down scan operation of the scan operation,
the second through via is driven to a ground voltage through a first NMOS transistor after the start of the down scan operation of the scan operation,
the first through via is driven to the ground voltage through a second N-type Metal-Oxide-Semiconductor (NMOS) transistor after a start of an up scan operation of the scan operation, and
the second through via is driven to the source voltage through a second PMOS transistor after the start of the up scan operation of the scan operation.

14. The memory device of claim 10, wherein the base chip detects a first open fail in which the signal path is disconnected when the logic level of the internal node is a level of a ground voltage after a start of a down scan operation of the scan operation.

15. The memory device of claim 10, wherein the base chip detects a second open fail in which a connection between a through via and a micro bump included in the signal path are weakly connected when the logic level of the internal node does not equal or exceed a level of a source voltage after a start of a down scan operation of the scan operation.

16. The memory device of claim 10, wherein the base chip detects a first short fail in which the signal path and a ground voltage applied to the voltage path are weakly connected when the logic level of the internal node does not equal or exceed a level of a source voltage after a start of a down scan operation and up scan operation of the scan operation.

17. The memory device of claim 10, wherein the base chip detects a second short fail in which the signal path and a ground voltage applied to the voltage path are strongly connected when the logic level of the internal node is a level of the ground voltage after the start of a down scan operation and up scan operation of the scan operation.

18. The memory device of claim 10, wherein the base chip detects a third short fail in which the signal path and a source voltage are connected when the logic level of the internal node is a level of the source voltage after a start of a down scan operation and up scan operation of the scan operation.

19. The memory device of claim 10, wherein the base chip comprises:
a test control circuit configured to generate a down scan signal and an up scan signal from a down enable signal and an up enable signal that perform the scan operation and configured to generate a down latch signal and an up latch signal that latch the logic level of the internal node based on a test delay signal and a test selection signal;
a base test circuit configured to drive the signal path based on the down scan signal and the up scan signal and configured to generate a fail detection signal based on the logic level of the internal node when the down latch signal and the up latch signal are generated; and
a fail detection circuit configured to detect the connection fail of the signal path based on the fail detection signal.

20. The memory device of claim 19, wherein the test control circuit comprises:
a buffer circuit configured to generate the down scan signal and the up scan signal by respectively buffering the down enable signal and the up enable signal;
a cycle signal generation circuit configured to generate a cycle signal comprising a pulse that is periodically generated by detecting timing at which the down scan operation and the up scan signal are generated and configured to adjust a pulse width of the cycle signal based on the test delay signal;
a scan pulse generation circuit configured to generate a scan pulse from any one of a plurality of counting signals that is generated by counting the cycle signal based on the test selection signal; and
a latch signal generation circuit configured to generate the down latch signal based on the scan pulse when the down scan signal is enabled and configured to generate the up latch signal based on the scan pulse when the up scan signal is enabled.

21. The memory device of claim 20, wherein the cycle signal generation circuit comprises:
a detection signal generation circuit configured to generate a detection signal that is enabled when any one of the down scan operation and the up scan signal is generated;
an enable signal generation circuit configured to generate an enable signal that is enabled from timing at which the detection signal is enabled to timing at which a reset signal is enabled; and
an oscillator configured to generate the cycle signal including the pulse width adjusted based on the enable signal and the test delay signal.

22. The memory device of claim 20, wherein the scan pulse generation circuit comprises:
a counter configured to generate the plurality of counting signals that is counted by the pulse included in the cycle signal;
a shifting circuit configured to generate the scan pulse from any one of the plurality of counting signals based on the test selection signal; and
a reset signal generation circuit configured to generate a reset signal that is enabled when all of the plurality of counting signals are counted.

23. The memory device of claim 20, wherein the latch signal generation circuit comprises:
a latch selection pulse generation circuit configured to output the scan pulse as a latch selection pulse based on a test control signal; and
a logic circuit configured to generate the down latch signal based on the latch selection pulse when the down scan signal is enabled and configured to generate the up latch signal based on the latch selection pulse when the up scan signal is enabled.
